(19) United States
(12) Patent Application Publication
(10) Pub. No.: US 2015/0311125 A1
(43) Pub. Date: Oct. 29, 2015

(54) SEMICONDUCTOR DEVICE AND METHOD OF MANUFACTURING THE SAME

(71) Applicants: Semiconductor Manufacturing International (Beijing) Corporation, Beijing (CN); Semiconductor Manufacturing International (Shanghai) Corporation, Shanghai (CN)

(72) Inventors: Jianhua JU, Shanghai (CN); ShaoFeng YU, Shanghai (CN)

(21) Appl. No.: 14/593,917

(22) Filed: Jan. 9, 2015

(30) Foreign Application Priority Data
Apr. 24, 2014 (CN) 201410166586.9

(51) Int. Cl. H01L 21/8238; H01L 27/092

(52) U.S. Cl. CPC H01L 21/823821; H01L 21/823807; H01L 27/0924

(57) ABSTRACT

A method of manufacturing a semiconductor CMOS device is provided. The method includes providing a semiconductor substrate, forming a first fin in a PMOS region and a second fin in an NMOS region of the semiconductor substrate, forming shallow trench isolation structures on the semiconductor substrate on opposite sides of the first and second fins, and performing ion implantation so as to implant germanium atoms into the first fin to form a silicon-germanium layer in the PMOS region. The silicon-germanium layer is used to adjust a work function of the PMOS region. The method further includes forming a stack structure in the PMOS region and the NMOS region, whereby the stack structure comprises a work function layer and a metal gate.

### CROSS-REFERENCE TO RELATED APPLICATION

This application claims priority to Chinese Patent Application No. 201410166586.9 filed on Apr. 24, 2014, the disclosure of which is incorporated herein by reference in its entirety.

### BACKGROUND

1. Technical Field

The present disclosure relates to the field of semiconductor technology, and more particularly to a semiconductor device and method of manufacturing the same.

2. Description of the Related Art

In the field of semiconductor technology, fin-type field effect transistor (FinFET), n-type metal-oxide-semiconductor (NMOS), and p-type metal-oxide-semiconductor (PMOS) often require different work function layer/metal gate stack structures in order to meet the threshold voltage requirements of long channel devices.

As the channel length reduces to 14 nm or 10 nm, gap filling during formation of the metal gate becomes an issue. To improve manufacturing yield, there is a need to simplify the materials and processes such that the NMOS and PMOS use the same work function layer/metal gate stack structure. Preferably, both the NMOS and PMOS should use a single work function layer/metal gate stack structure.

Currently, there are several simplified “multi work function layer/metal gate (multi-WFMG)” methods that may be used in the manufacture of a semiconductor device.

For example, one of the methods may include forming a silicon-germanium (SiGe) channel via epitaxial growth in the PMOS region and subsequently forming a single WFMG stack. The structure forming using the aforementioned method can deliver device performance similar to that obtained using different work function layer/metal gate stack structures.

In addition to the above method, another method may include forming a single WFMG stack and performing ion implantation (e.g. implanting As, Al, etc.) on the single WFMG stack to adjust the work function of the NMOS or PMOS. Similarly, the structure formed using the aforementioned method can deliver the device performance similar to that obtained using different work function layer/metal gate stack structures.

However, the above-described methods have several shortcomings. For example, the first method requires a SiGe channel epitaxy process, which can be difficult to control. As for the latter method, it is often difficult to control threshold voltage mismatch, which may result in random doping fluctuations in the threshold voltage.

### SUMMARY

The present disclosure addresses at least the above issues in the prior art.

According to one embodiment of the inventive concept, a method of manufacturing a semiconductor device is provided. The method includes: providing a semiconductor substrate; forming a first fin in a PMOS region and a second fin in an NMOS region of the semiconductor substrate; forming shallow trench isolation structures on the semiconductor substrate on opposite sides of the first and second fins; performing ion implantation so as to implant germanium atoms into the first fin to form a silicon-germanium layer in the PMOS region, wherein the silicon-germanium layer is used to adjust a work function of the PMOS region; and forming a stack structure in the PMOS region and the NMOS region, wherein the stack structure comprises a work function layer and a metal gate.

In one embodiment, the ion implantation may be performed using a high temperature and high current ion beam implantation apparatus.

In one embodiment, the ion implantation may be performed at a process temperature ranging from about 300° C. to about 400° C.

In one embodiment, the performing of the ion implantation may further include: forming a mask layer on the semiconductor substrate, wherein the mask layer is formed covering the NMOS region while exposing the PMOS region; performing the ion implantation through the mask layer to implant the germanium atoms into the first fin to form the silicon-germanium layer in the PMOS region; and removing the mask layer.

In one embodiment, the ion implantation may be performed sequentially on a first side and a second side of the first fin in the PMOS region.

In one embodiment, the method may further include performing thermal oxidation to increase a concentration of the germanium atoms near a surface of the first fin in the PMOS region.

In one embodiment, the forming of the shallow trench isolation structures may further include: depositing a dielectric material on the semiconductor substrate; removing portions of the dielectric material protruding above the first and second fins using chemical mechanical polishing (CMP), the remaining dielectric material forming a shallow trench isolation layer; and etching back the shallow trench isolation layer to form a plurality of shallow trench isolation structures, wherein at least a portion of sidewalls of the first and second fins may be exposed.

In one embodiment, the dielectric material may be deposited using flowable chemical vapor deposition (FCVD).

In one embodiment, the first and second fins may be formed by etching.

In one embodiment, the gate stack structure may be the same in both the PMOS region and the NMOS region.

According to another embodiment of the inventive concept, a semiconductor CMOS device is provided. The semiconductor device includes: a semiconductor substrate including a PMOS region and an NMOS region; a first fin disposed in the PMOS region and a second fin disposed in the NMOS region; and a silicon-germanium layer disposed in the first fin in the PMOS region, wherein the silicon-germanium layer is used to adjust a work function of the PMOS region.

In one embodiment, the silicon-germanium layer may be disposed near a surface of the first fin in the PMOS region.

In one embodiment, the semiconductor device may further include shallow trench isolation structures disposed on the semiconductor substrate on opposite sides of the first and second fins.

In one embodiment, the semiconductor device may further include a stack structure disposed in the PMOS region and the NMOS region, wherein the stack structure includes a work function layer and a metal gate.

In one embodiment, the stack structure may be the same in both the PMOS region and the NMOS region.

### BRIEF DESCRIPTION OF THE DRAWINGS

The accompanying drawings, which are incorporated herein and constitute a part of the specification, illustrate different embodiments of the inventive concept and, together with the detailed description, serve to describe more clearly the inventive concept.

It is noted that in the accompanying drawings, for convenience of description, the dimensions of the components shown may not be drawn to scale. Also, same or similar reference numbers between different drawings represent the same or similar components.

FIGS. 1A, 1B, 1C, 1D, and 1E depict schematic cross-sectional views of a semiconductor device at different stages of manufacture according to an embodiment.

FIG. 2 is a flowchart illustrating a method of manufacturing a semiconductor device according to an embodiment.

FIG. 3 depicts a schematic cross-sectional view of a semiconductor device according to an embodiment.

FIG. 4 is a schematic diagram of an electronic apparatus according to an embodiment.

### DETAILED DESCRIPTION

Various embodiments of the inventive concept are next described in detail with reference to the accompanying drawings. It is noted that the following description of the different embodiments is merely illustrative in nature, and is not intended to limit the inventive concept, its application, or use. The relative arrangement of the components and steps, and the numerical expressions and the numerical values set forth in these embodiments do not limit the scope of the inventive concept unless otherwise specifically stated. In addition, techniques, methods, and devices as known by those skilled in the art, although omitted in some instances, are intended to be part of the specification where appropriate. It should be noted that for convenience of description, the sizes of the elements in the drawings may not be drawn to scale.

In the drawings, the sizes and/or relative sizes of layers and regions may be exaggerated for clarity. Like reference numerals denote the same elements throughout.

It should be understood that when an element or layer is referred to as “in”, “adjacent to”, “connected to”, or “coupled to” another element or layer, it can be directly on the other element or layer, adjacent, connected or coupled to the other element or layer. In some instances, one or more intervening elements or layers may be present. In contrast, when an element is referred to as being “directly on”, “directly adjacent to”, “directly connected to”, or “directly coupled to” another element or layer, there are no intervening elements present or layer. It will be understood that, although the terms “first,” “second,” “third,” etc. may be used herein to describe various elements, the elements should not be limited by those terms. Instead, those terms are merely used to distinguish one element from another. Thus, a “first” element discussed below could be termed a “second” element without departing from the teachings of the present inventive concept. As used herein, the term “and/or” includes any and all combinations of one or more of the associated listed items.

Spatially relative terms, such as “beneath”, “below”, “lower”, “above”, “upper” and the like, may be used herein for ease of description to describe one element or feature's spatial relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments and is not intended to limit the inventive concept. As used herein, the singular forms “a”, “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art, and should not be interpreted in an idealized or overly formal sense unless expressly so defined herein.

Exemplary embodiments are described herein with reference to cross-sectional illustrations that are schematic illustrations of idealized exemplary embodiments (and intermediate structures) of the inventive concept. As such, variations from the shapes of the illustrations as a result of, for example, manufacturing techniques and/or tolerances, are to be expected. Thus, the exemplary embodiments should not be construed as being limited to the particular shapes of regions illustrated herein, but may also include deviations in shapes that result, for example, from manufacturing tolerances. The regions illustrated in the figures are schematic in nature, and their shapes are not intended to illustrate the actual shape of a region of a device, and should not be construed to limit the scope of the inventive concept.

It should be understood that the inventive concept is not limited to the embodiments described herein. Rather, the inventive concept may be modified in different ways to realize different embodiments.

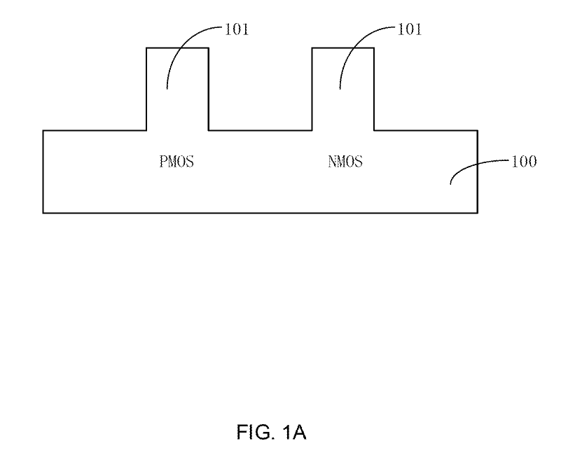

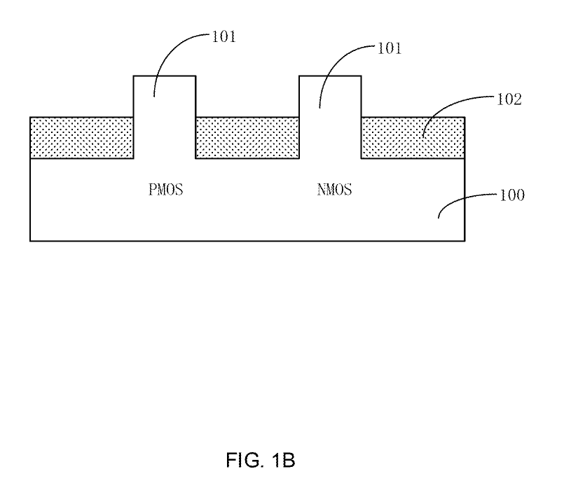

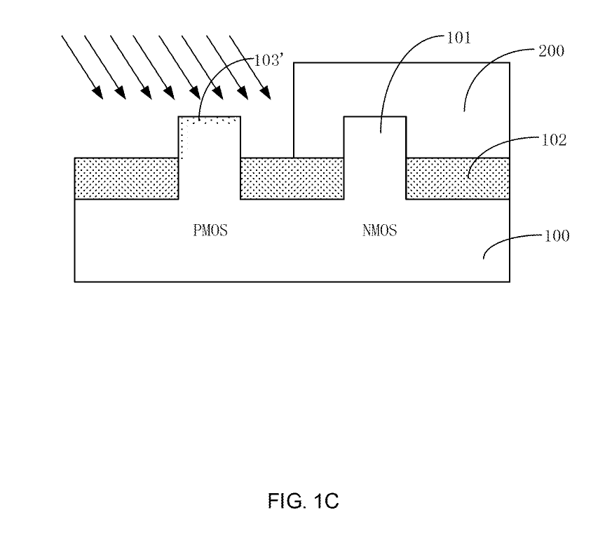

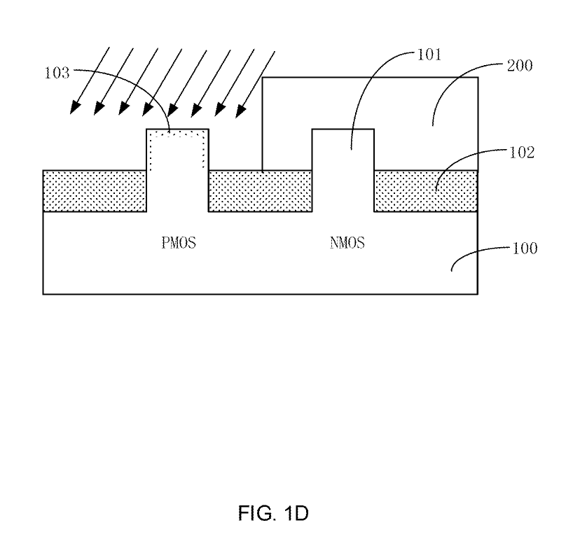

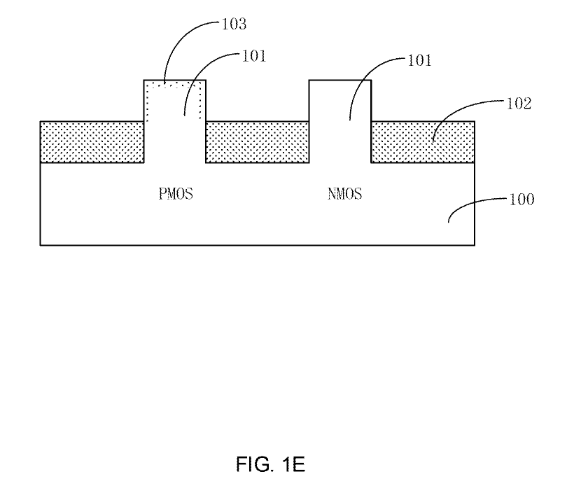

First, a method of manufacturing a semiconductor device according to an embodiment will be described in detail with reference to FIGS. 1A though 1E. Specifically, FIGS. 1A though 1E depict schematic cross-sectional views of the semiconductor device at different stages of manufacture. The semiconductor device includes a single work function layer/metal gate stack structure. The semiconductor device also includes NMOS, PMOS, and FinFET. The method includes the following steps.

In Step A1, a semiconductor substrate 100 is provided. The semiconductor substrate 100 may be a single crystal silicon substrate or any other appropriate substrate. FinFETs including fins 101 are formed on the semiconductor substrate 100. Specifically, the fins 101 are formed on a PMOS region and an NMOS region, as shown in FIG. 1A. The fins 101 may be formed through etching or any other suitable method.

In Step A2, shallow trench isolation (STI) structures 102 are formed on the semiconductor substrate 100 on opposite sides of the fins 101, as shown in FIG. 1B. Specifically, Step A2 includes Steps A201 through A203, described below.

In Step A201, a dielectric material is deposited on the semiconductor substrate 100, the dielectric material covering the fins 101 and the gaps between adjacent fins 101. In one embodiment, the dielectric material may be deposited using flowable chemical vapor deposition (FCVD). It is noted that the film quality of the dielectric material can be improved when the dielectric material is deposited using FCVD.

In Step A202, the portions of the dielectric material protruding above the fins 101 are removed using chemical mechanical polishing (CMP). The remaining dielectric material forms a shallow trench isolation layer.

In Step A203, the shallow trench isolation layer is etched back to form the STI structures 102, thereby exposing at least a portion of the sidewall of the fins 101. The purpose of Step A203 is to form a recess on opposite sides of the fins 101 and to expose a portion of the fins 101. Step A203 is commonly known as a “fin pull-back” process.

The resulting structure formed after Step A203 is illustrated in FIG. 1B.

In Step A3, ion implantation is performed to implant germanium atoms into the fin 101 in the PMOS region, so as to form a silicon-germanium layer 103. The silicon-germanium layer 103 can be used to adjust the work function of the PMOS.

In one embodiment, the silicon-germanium layer 103 can be used as a PMOS channel.

Step A3 further includes Steps A301 through A303, described below.

In Step A301, a mask layer 200 is formed on the semiconductor substrate 100 covering the NMOS region while exposing the PMOS region. The mask layer 200 may be a photoresist or any other suitable masking material.

In Step A302, ion implantation is performed through the mask layer 200, as shown in FIGS. 1C and 1D. As previously described, germanium atoms are implanted into the fin 101 in the PMOS region, so as to form the silicon-germanium layer 103. The mask layer 200 is removed after the ion implantation has been completed.

In one embodiment, for example as shown in FIGS. 1C and 1D, ion implantation is performed sequentially on each side (of the opposing sides) of the fin 101 in the PMOS region. A partial silicon-germanium layer 103′ is formed after ion implantation has been performed on one side of the fin 101 in the PMOS region, as shown in FIG. 1C. Subsequently, the full silicon-germanium layer 103 is formed after ion implantation has been performed on both sides of the fin 101 in the PMOS region, as shown in FIG. 1D. The silicon-germanium layer 103 is disposed near a top surface of the fin 101 in the PMOS region. Accordingly, after the ion implantation, a Ge-rich layer is formed in the fin 101 disposed in the PMOS region.

In one embodiment, the ion implantation may be performed using a high temperature and high current beam ion implantation apparatus. The process temperature of the ion implantation may vary from about 300° C. to about 400° C. In performing the ion implantation using the high temperature and high current beam ion implantation apparatus, a highly concentrated silicon-germanium layer 103 can be formed in the surface of fin 101 disposed in the PMOS region. Damage to the fin 101 in the PMOS region is typically less using the high temperature and high current beam ion implantation apparatus (compared to ion implantation using other apparatuses).

As previously mentioned, the silicon-germanium layer 103 is disposed near a surface of the fin 101 in the PMOS region (see for example, FIG. 1E). The silicon-germanium layer 103 has a high Ge dopant concentration (atomic percentage).

The silicon-germanium layer 103 can be used to adjust the work function of the PMOS. Specifically, the work function of the PMOS can be adjusted by controlling the ion implantation dosage of the germanium atoms. Accordingly, a semiconductor CMOS device having a single work function layer/metal gate stack structure may be realized using the above embodiment, as described later in Step A4.

In some embodiments, a Step A303 may be performed after Step A302. In Step A303, thermal oxidation is performed to increase the concentration of germanium atoms near the surface of the fin 101 in the PMOS region. Specifically, an oxide layer is formed on the silicon-germanium layer 103 using thermal oxidation, and condensation effect in the oxide layer can cause the germanium atoms to diffuse to the bottom region of the oxide layer, thereby increasing the concentration of the germanium atoms at the inner side surface region of the fin 101 in the PMOS region.

By increasing the concentration of the germanium atoms, the adjustment of the work function of the PMOS can be further improved. First, an initial work function of the PMOS and an initial work function of the NMOS can be adjusted to have a predetermined difference. The initial work function refers to the value of the work function prior to the work function layer being formed. Next, a stack structure comprising the work function layer and the metal gate is formed, with both the PMOS and NMOS using the same stack structure. The work function difference between the PMOS and NMOS can be achieved by adjusting the concentration of germanium atoms in the silicon-germanium layer 103.

In Step A4, the stack structure comprising the work function layer and the metal gate is formed in the PMOS region and NMOS region. The stack structure may be formed at the same time in the PMOS and NMOS regions. The stack structure is the same in both the PMOS and NMOS regions. Accordingly, the above stack structure constitutes a single work function layer/metal gate stack structure.

As previously mentioned in the Background Section, one of the simplified “multi work function layer/metal gate (multi-WFMG)” methods may include forming a silicon-germanium (SiGe) channel via epitaxial growth in the PMOS region and forming a single WFMG stack. However, the aforementioned method requires a SiGe channel epitaxy process, which can be difficult to control. In contrast, the exemplary method described in Steps A1 through A4 does not require a silicon-germanium channel epitaxial process, and thus can be more easily controlled.

Also, as previously mentioned in the Background Section, another simplified “multi work function layer/metal gate (multi-WFMG)” methods may include forming a single WFMG stack and performing ion implantation (e.g. implanting As, Al, etc.) on the single WFMG stack to adjust the work function of the NMOS or PMOS. However, in the aforementioned method, it is often difficult to control threshold voltage mismatch, which may result in random doping fluctuations in the threshold voltage. In contrast, using the exemplary method described in Steps A1 through A4, the threshold voltage mismatch problem can be avoided, and therefore random fluctuations in the threshold voltage will not result. Furthermore, the semiconductor PMOS device performance can be improved by using a single work function layer/metal gate stack structure. Accordingly, the above exemplary method can simplify the process flow, and improve the yield and performance of the semiconductor device.

In the exemplary method of manufacturing the semiconductor CMOS device, a silicon-germanium layer is formed by performing ion implantation on the fin in the PMOS region. The silicon-germanium layer can be used to adjust the work function of the PMOS. The semiconductor device includes a single work function layer/metal gate stack structure. Accordingly, the yield and performance of the semiconductor device can be improved.

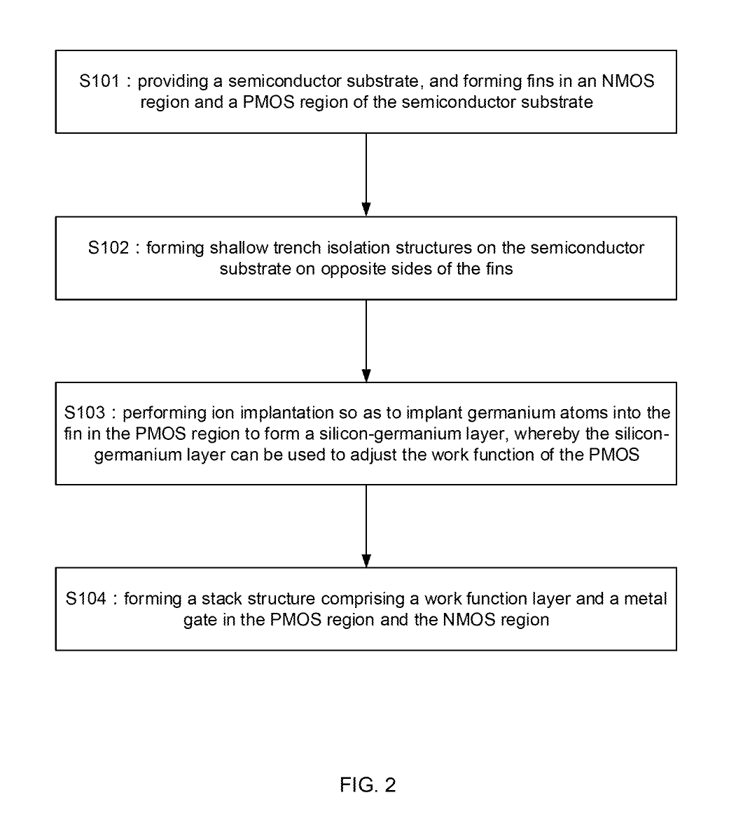

FIG. 2 is a flowchart illustrating a method of manufacturing a semiconductor CMOS device according to an embodiment. The method of FIG. 2 may include some or all of the previously-described Steps A1 through A4 including the sub-steps. Specifically, the method of FIG. 2 includes the following steps.

Step S101: providing a semiconductor substrate, and forming fins in an NMOS region and a PMOS region of the semiconductor substrate.

Step S102: forming shallow trench isolation structures on the semiconductor substrate on opposite sides of the fins.

Step S103: performing ion implantation so as to implant germanium atoms into the fin in the PMOS region to form a silicon-germanium layer, whereby the silicon-germanium layer can be used to adjust the work function of the PMOS.

Step S104: forming a stack structure comprising a work function layer and a metal gate in the PMOS region and the NMOS region.

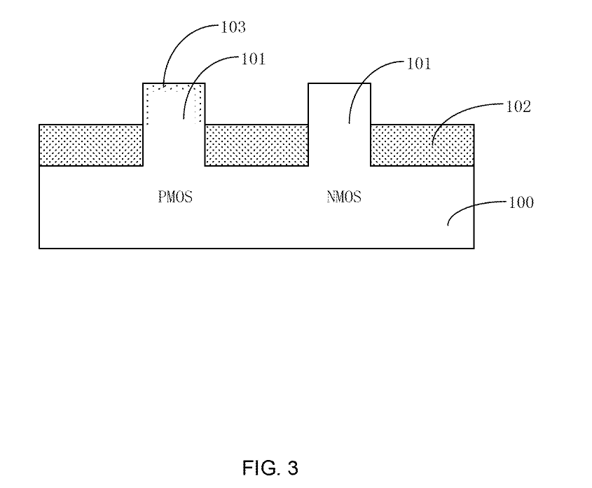

Next, a semiconductor CMOS device according to an embodiment of the inventive concept will be described with reference to FIG. 3. The semiconductor device may be manufactured using the method described in FIG. 2 and Steps A1 through A4.

Referring to FIG. 3, the semiconductor CMOS device includes fins 101 disposed in an NMOS region and a PMOS region on a semiconductor substrate 100. The semiconductor device further includes a silicon-germanium layer 103 in the fin 101 in the PMOS region. The silicon-germanium layer 103 can be used to adjust the work function of the PMOS. As shown in FIG. 3, the silicon-germanium layer 103 is disposed near a surface of the fin 101 in the PMOS region.

In one embodiment, the semiconductor device further includes shallow isolation trench structures 102 disposed on the semiconductor substrate 100 on opposite sides of the fins 101. In one embodiment, the shallow isolation trench structures 102 may be formed of silicon oxide.

In one embodiment, the semiconductor device further includes a stack structure comprising a work function layer and a metal gate in the PMOS region and the NMOS region. The stack structure is the same in both the PMOS and NMOS regions. Accordingly, the semiconductor device uses a single work function layer/metal gate stack structure.

In the exemplary semiconductor device, a silicon-germanium layer is formed in the fin in the PMOS region. The silicon-germanium layer can be used to adjust the work function of the PMOS. Also, the semiconductor device includes a single work function layer/metal gate stack structure. Accordingly, the performance of the semiconductor PMOS device can be improved.

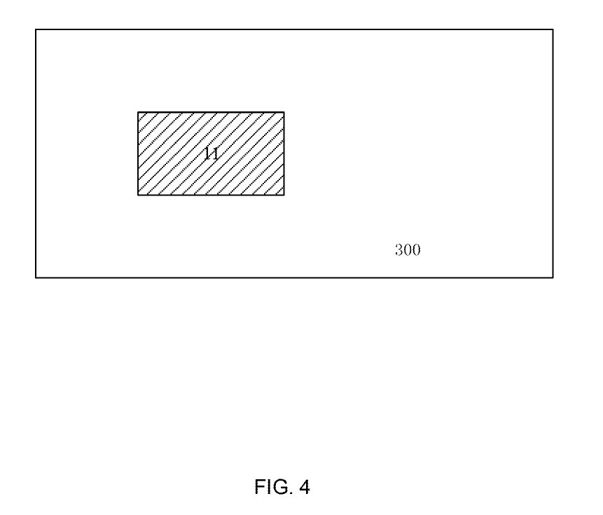

FIG. 4 is a schematic diagram of an electronic apparatus 300 according to an embodiment.

Referring to FIG. 4, the electronic apparatus 300 includes a semiconductor device 11. The semiconductor device 11 may be the semiconductor device described previously with reference to FIG. 3. Alternatively, the semiconductor device 11 may a semiconductor device that is manufactured using the using the method described in FIG. 2 and Steps A1 through A4.

The electronic apparatus 300 may include mobile phones, tablet PCs, laptops, netbooks, game consoles, TVs, VCD players, DVD players, navigation systems, cameras, video cameras, voice recorders, MP3/MP4 players, PSPs, or any other electronic products or devices. The electronic apparatus 300 may also include intermediate (unfinished) products comprising the semiconductor device 11.

The semiconductor device 11 has improved performance since it includes a single work function layer/metal gate stack structure, and a silicon-germanium layer that can be used to adjust the work function of the PMOS. Since the semiconductor device 11 is incorporated into the electronic apparatus 300, the performance of the electronic apparatus 300 is thus improved.

Embodiments of a semiconductor device and a method of manufacturing the semiconductor device have been described in the foregoing description. To avoid obscuring the inventive concept, details that are well-known in the art may have been omitted. Nevertheless, those skilled in the art would be able to understand the implementation of the inventive concept and its technical details in view of the present disclosure.

Different embodiments of the inventive concept have been described with reference to the accompanying drawings. However, the different embodiments are merely illustrative and are not intended to limit the scope of the inventive concept. Furthermore, those skilled in the art would appreciate that various modifications can be made to the different embodiments without departing from the scope of the inventive concept.

What is claimed is:

1. A method of manufacturing a semiconductor CMOS device, comprising:
providing a semiconductor substrate;
forming a first fin in a PMOS region and a second fin in an NMOS region of the semiconductor substrate;
forming shallow trench isolation structures on the semiconductor substrate on opposite sides of the first and second fins;
performing ion implantation so as to implant germanium atoms into the first fin to form a silicon-germanium layer in the PMOS region, wherein the silicon-germanium layer is used to adjust a work function of the PMOS region; and
forming a stack structure in the PMOS region and the NMOS region, wherein the stack structure comprises a work function layer and a metal gate.

2. The method according to claim 1, wherein the ion implantation is performed using a high temperature and high current ion beam implantation apparatus.

3. The method according to claim 1, wherein the ion implantation is performed at a process temperature ranging from about 300° C. to about 400° C.

4. The method according to claim 1, wherein the performing of the ion implantation further comprises:
forming a mask layer on the semiconductor substrate, wherein the mask layer is formed covering the NMOS region while exposing the PMOS region;
performing the ion implantation through the mask layer to implant the germanium atoms into the first fin to form the silicon-germanium layer in the PMOS region; and
removing the mask layer.

5. The method according to claim 4, wherein the ion implantation is performed sequentially on a first side and a second side of the first fin in the PMOS region.

6. The method according to claim 4, further comprising:
performing thermal oxidation to increase a concentration of the germanium atoms near a surface of the first fin in the PMOS region.

7. The method according to claim 1, wherein the forming of the shallow trench isolation structures further comprises:
depositing a dielectric material on the semiconductor substrate;
removing portions of the dielectric material protruding above the first and second fins using chemical mechanical polishing (CMP), the remaining dielectric material forming a shallow trench isolation layer; and
etching back the shallow trench isolation layer to form a plurality of shallow trench isolation structures, wherein at least a portion of sidewalls of the first and second fins is exposed.

8. The method according to claim 7, wherein the dielectric material is deposited using flowable chemical vapor deposition (FCVD).

9. The method according to claim 1, wherein the first and second fins are formed by etching.

10. The method according to claim 1, wherein the stack structure is the same in both the PMOS region and the NMOS region.

11. A semiconductor CMOS device, comprising:
a semiconductor substrate including a PMOS region and an NMOS region;
a first fin disposed in the PMOS region and a second fin disposed in the NMOS region; and
a silicon-germanium layer disposed in the first fin in the PMOS region, wherein the silicon-germanium layer is used to adjust a work function of the PMOS region.

12. The semiconductor device according to claim 11, wherein the silicon-germanium layer is disposed near a top surface of the first fin in the PMOS region.

13. The semiconductor device according to claim 11, further comprising:
shallow trench isolation structures disposed on the semiconductor substrate on opposite sides of the first and second fins.

14. The semiconductor device according to claim 11, further comprising:
a stack structure disposed in the PMOS region and the NMOS region, wherein the stack structure includes a work function layer and a metal gate.

15. The semiconductor device according to claim 14, wherein the stack structure is the same in both the PMOS region and the NMOS region.
